(19) United States
(12) Patent Application Publication
(10) Pub. No.: US 2026/0206517 A1
(43) Pub. Date: Jul. 16, 2026

(54) SYSTEM FOR DIAGNOSING PVD CHAMBER FOR MANUFACTURING SEMICONDUCTOR

(71) Applicant: SPSGLOBAL Co., Ltd, Cheonan-si (KR)

(72) Inventor: Sang Hyub LEE, Cheonan-si (KR)

(21) Appl. No.: 19/020,357

(22) Filed: Jan. 14, 2025

(30) Foreign Application Priority Data
Jan. 10, 2025 (KR) 10-2025-0004099

(51) Int. Cl. H01L 21/67

(52) U.S. Cl. CPC H10P 72/00

(57) ABSTRACT

A system for diagnosing a PVD chamber for manufacturing semiconductor involves installing and operating diagnostic equipment storage facilities at various places for each company and each factory in order to enhance the efficiency in transportation of diagnostic equipment and use and replacement of an operating system program for diagnostic equipment for PVD chambers. When it is required to replace an operating system program on the basis of the position, type, and condition of a PVD chamber, the system locates a nearest diagnostic equipment storage facility and is supplied with the required equipment.

### CROSS REFERENCE TO RELATED APPLICATION

The present application claims priority from Korean Patent Applications No. 10-2025-0004099, filed Jan. 10, 2025, which is incorporated herein by reference in its entirety.

### BACKGROUND

### 1. Technical Field

The present disclosure relates to a physical vapor deposition (PVD) chamber for manufacturing semiconductors, and a method and system for diagnosing the PVD chamber.

### 2. Description of the Related Art

In general, PVD chambers for manufacturing semiconductors need to be precisely and quickly driven to perform a semiconductor manufacturing process. However, when PVD chambers are used for a long period of time, they may operate inaccurately, and inspection, maintenance, and repair are necessary.

Test systems for PVD chambers for manufacturing semiconductor in the related art rely on proprietary operating system programs developed by the manufacturers of the PVD equipment, and those programs are not easily compatible with general-purpose industrial equipment at industrial sites when inspecting, maintaining, or repairing robots.

The related art to this background is as follows.

### RELATED ART DOCUMENTS

### Patent Documents

(Document 1) Korean Patent No. 10-0875356

(Document 2) Korean Patent No. 10-1968691

(Document 1) European Patent No. 00834180

### SUMMARY

The present disclosure, in a system for diagnosing a PVD chamber for manufacturing semiconductors, involves installing and operating diagnostic equipment storage facilities at various places for each company and each factory in order to enhance the efficiency in transportation of diagnostic equipment and use and replacement of an operating system program for diagnostic equipment for PVD chambers.

An objective of the present disclosure is to provide a system for diagnosing a PVD chamber for manufacturing semiconductors, the system can locate a nearest diagnostic equipment storage facility and can be supplied with the required equipment when it is required to replace an operating system program on the basis of the position, type, and condition of a PVD chamber.

A system for diagnosing a PVD chamber for manufacturing semiconductors according to an embodiment first includes: multiple pieces of diagnostic equipment for testing a PVD chamber for each factory; and a control center configured to remotely manage a use state of an operating system program for the diagnostic equipment in conjunction with the diagnostic equipment, wherein the diagnostic equipment performs: a first step of testing a corresponding PVD chamber using an operating system program type supplied from the control center; a second step of setting a type of the PVD chamber in the first step; a third step of classifying PVD chamber types in accordance with types of operating system program types of the diagnostic equipment and setting one of the types for the type of the PVD chamber in the second step, and detecting usage of the operating system program after the second step; a fourth step of comparing the usage detected in the third step with a set threshold; a fifth step of detecting a position of the PVD chamber when the detected usage is the threshold or more in the fourth step; and a sixth step of transmitting the type, position, and operating system program replacement request information of the PVD chamber to the control center in the fifth step, and the control center performs: a first step of setting and registering a type and a position of the operating system program of a diagnostic equipment storage facility for a type and a position of each PVD chamber; a second step of collecting the type, position, and operating system program replacement request information of a PVD chamber for each of the PVD chambers through the diagnostic equipment in the first step; a third step of extracting the operating system program and the position of a diagnostic equipment storage facility closest to the types and positions of the PVD chambers collected in the second step from the registration information; and a fourth step of transmitting the information extracted in the third step to a corresponding diagnostic equipment.

According to embodiments, a system for diagnosing a PVD chamber for manufacturing semiconductor involves installing and operating diagnostic equipment storage facilities at various places for each company and each factory in order to enhance the efficiency in transportation of diagnostic equipment and use and replacement of an operating system program for diagnostic equipment for PVD chambers.

When it is required to replace an operating system program on the basis of the location, type, and condition of a PVD chamber, it is possible to locate a nearest diagnostic equipment storage facility and it is possible to be supplied with the required equipment.

### BRIEF DESCRIPTION OF THE DRAWINGS

FIG. 1 is a conceptual diagram of a system for diagnosing a PVD chamber for manufacturing semiconductors according to a first embodiment;

FIG. 2 is a flowchart of a system according to a second embodiment; and

FIG. 3 is a flowchart of a system according to a third embodiment.

### DETAILED DESCRIPTION

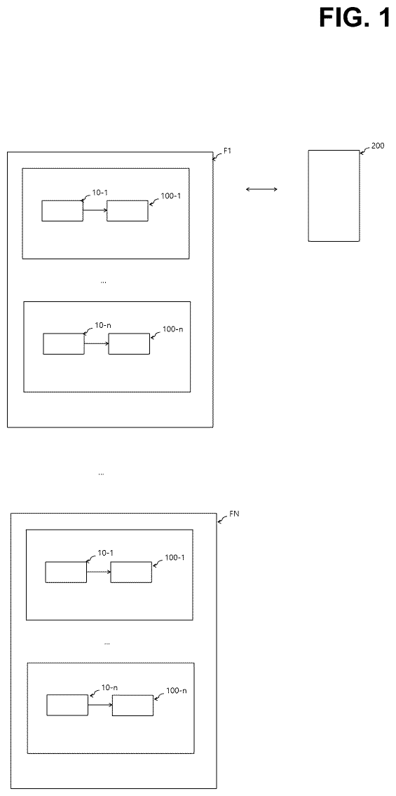

FIG. 1 is a conceptual diagram of a system for diagnosing a PVD chamber for manufacturing semiconductors according to a first embodiment.

As shown in FIG. 1, a system according to a first embodiment first, in a system for diagnosing a PVD chamber for manufacturing semiconductor, involves installing and operating diagnostic equipment storage facilities at various places for each company and each factory in order to enhance the efficiency in transportation of diagnostic equipment and use and replacement of an operating system program for diagnostic equipment for PVD chambers.

When it is required to replace an operating system program on the basis of the position, type, and condition of a PVD chamber, the present disclosure enables locating a nearest diagnostic equipment storage facility and being supplied with the required equipment.

To this end, the system according to the first embodiment includes diagnostic equipment 100 for a PVD chamber 10 and a control center 200.

The diagnostic equipment 100 is for testing the PVD chamber 10 for each company and each factory F. The diagnostic equipment 100 includes a jig body connected to the PVD chamber 10, a test wafer, and a wafer transfer unit inserting and removing the test wafer into and from the PVD chamber 10. The PVD chamber 10 includes a slit valve passing through a wafer and a magnetic rotor generating a magnetic field in a PVD process.

The control center 200 remotely manages the use state of the operating system program for the diagnostic equipment 100 in conjunction with the diagnostic equipment 100. The control center 200 involves installing and operating diagnostic equipment storage facilities at various places for each company and each factory in order to enhance the efficiency in transportation of diagnostic equipment and use and replacement of an operating system program for diagnostic equipment for PVD chambers. Accordingly, when it is required to replace an operating system program on the basis of the position, type, and condition of a PVD chamber, the system locates a nearest diagnostic equipment storage facility and is supplied with the required equipment. For example, diagnostic equipment storage facilities are divided into multiple areas for each company and factory, and at least one facility is installed in each area. Each area is provided with at least one or more various operating system program types. The operating system program types can be classified on the basis of the performance, capacity, and type of PVD chambers. For example, they are defined as a small scale, a medium scale, and a large scale. The small scale, medium scale, and large scale are determined on the basis of the performance, capacity, and type of PVD chambers.

The diagnostic equipment 100 is as follows.

The jig body includes a first sensor measuring pressure of 10-9 Torr in the PVD chamber 10, a second sensor measuring the temperature thereof, a third sensor measuring displacement of the slit valve, and a fourth sensor measuring rotation of the magnetic rotor. The test wafer includes a fifth sensor measuring vertical displacement thereof and a sixth sensor measuring a magnetic field that is applied to the test wafer.

A test controller includes a motion board that controls driving of the PVD chamber 10 and the wafer transfer unit, a Digital I/O (DIO) board that controls digital input/output of the first sensor to the sixth sensor, and an analog I/O (AIO) board that controls analog input/output.

A test PC includes a test program that controls the test controller and receives data of the first sensor to the sixth sensor collected by the test controller, and an image output unit that outputs the content of the test program as video data.

The test program generates a maintenance signal when the data of the first sensor to the sixth sensor deviates by 1% from a normal value.

A weight of 2 is assigned to the maintenance signal of the first sensor, a weight of 2 is assigned to the maintenance signal of the second sensor, a weight of 1 is assigned to the maintenance signal of the third sensor, a weight of 1 is assigned to the maintenance signal of the fourth sensor, a weight of 4 is assigned to the maintenance signal of the fifth sensor, and a weight of 3 is assigned to the maintenance signal of the sixth sensor. When the sum is 10 or more, a maintenance alert is triggered.

The test method of the diagnostic equipment 100 is as follows.

A jig body of the test jig is connected to a PVD chamber to be tested.

The first sensor to the fourth sensor of the jig body are installed on the PVD chamber.

The wafer transfer unit is installed on the slit valve of the PVD chamber.

A test wafer including the fifth sensor and the sixth sensor is mounted on the wafer transfer unit.

The test jig is connected to the test controller and the test controller is connected to the test PC.

The test program is executed and, the ID and P/W of a worker are entered on a LOGIN image.

The number of test executions is entered in a test execution count display section in a RECIPE image.

In a test step setting section of the RECIPE image, the operations of the PVD chamber and the test jig are set to operate in the same manner as the PVD chamber operates in a PVD process.

Operation ranges of the PVD chamber, the test jig, and the first sensor to sixth sensor are set in an individual setting section of a CONFIG image.

Position coordinates of the PVD chamber, the test jig, and the first sensor to sixth sensor are set in a position setting section of the CONFIG image.

A test is performed with the set values through an operation image display section and a work state display section of a MAIN image of the test program.

Events and the result of the test are checked through an event display section of the MAIN image.

The operation of the diagnostic equipment 100 is as follows.

First, a corresponding PVD chamber is tested through an operating system program of diagnostic equipment supplied from the control center 200.

Next, the type of the PVD chamber is set.

PVD chamber types are classified for the types of operating system program types of diagnostic equipment, and one of them is selected for the type of the PVD chamber.

The diagnostic equipment storage facility may be divided into multiple areas for each company and each factory, and at least one facility may be installed in each area. Each area is provided with at least one or more types of various operating system programs.

The operating system program types can be classified on the basis of the performance, capacity, type, etc. of a PVD chamber. For example, they are defined as a small scale, a medium scale, and a large scale. The small scale, medium scale, and large scale are determined on the basis of the performance, capacity, and type of PVD chambers. For example, types are ranked in order of 1, 2, ..., n, with lower performance and capacity corresponding to lower numbers.

In this state, the usage of the operation system program of the diagnostic equipment is detected. This is prior art.

The detected usage is compared with a set threshold.

When the detected usage is the threshold or more, as the result of the comparison, the position of the PVD chamber is detected.

The type, position, and operating system program replacement request information of the PVD chamber is transmitted to the control center 200.

The operation of the control center 200 is as follows.

The type and position of the operating system program of a diagnostic equipment storage facility are set and registered for the type and position of each PVD chamber.

In this state, type, position, and operating system program replacement request information of a PVD chamber is collected for each PVD chamber through the diagnostic equipment 100.

The operating system program and position of a diagnostic equipment storage facility closest to the collected types and positions of the PVD chambers are extracted from the registration information.

That is, an operating system program closest to the collected types of the PVD chambers are found out and a diagnostic equipment storage facility nearest to the position of a corresponding PVD chamber is found out from them.

The extracted information is transmitted to corresponding diagnostic equipment 100.

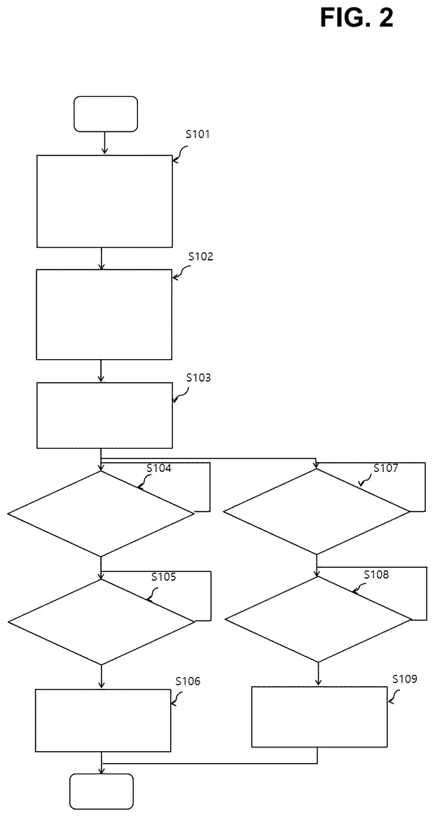

FIG. 2 is a conceptual diagram of the system according to a second embodiment.

Referring to FIG. 2, in the system according to the second embodiment, first, the control center 200 recommends an operating system program type of a diagnostic equipment storage facility.

This is transmitted to a PVD chamber or diagnostic equipment, and when the operating system program needs to be replaced, a storage facility of the operating system program corresponding to the type of a corresponding PVD chamber is found out and used.

The type value of the operating system program may be determined as various values, depending on the use ranges of PVD chambers, that is, demand for each position. When the demand is low, the value is low, and when the demand is high, the value is high.

The control center 200 can recommend different type values of the operating system program of a diagnostic equipment storage facility in accordance with the main use position and demand of PVD chambers.

The type values of operating system programs are sequentially classified.

For example, small, medium, and large scales are sequentially assigned to types 1, 2, and 3, respectively. As the type decreases, the demand decreases. That is, when the demand is low, a low type is used.

The control center 200 recommends the operating system program type of a diagnostic equipment storage facility in accordance with the usage and the demand of a PVD chamber. When it is required to replace an operating system program on the basis of recommended information, the PVD chamber finds out and uses a diagnostic equipment storage facility corresponding to the PVD chamber.

To this end, the control center 200 extracts a diagnostic equipment storage facility within a set use range from registered diagnostic equipment storage facilities.

The set use range is of a size recognizable as the same category or area and is intended to extract all diagnostic equipment storage facilities that are mainly used at the same place.

The average position of the extracted diagnostic equipment storage facilities is calculated (S102).

That is, main use positions are found out on the basis of the positions of diagnostic equipment storage facilities within the same use range and an average value is obtained from the position coordinate values of the diagnostic equipment storage facilities.

The calculated average position and the positions of the extracted diagnostic equipment storage facilities are compared (S103).

The average number of times of operating system program replacement requests of the extracted diagnostic equipment storage facilities is calculated.

That is, the usage is found out on the basis of the replacement request of each diagnostic equipment storage facility within the same use range.

The calculated average number of times for replacement and the number of times of replacement requests of each of the extracted diagnostic equipment storage facilities are compared.

As the result of the comparison, when the position of an extracted diagnostic equipment storage facility deviates by a first set value or more from the average position (S104) and the number of times of replacement requests of the extracted diagnostic equipment storage facility is less than or equal to a second set value compared to the average number of times of replacement requests (S105), the operating system program type of the diagnostic equipment storage facility is downgraded by one level (S106).

That is, when the position of a specific diagnostic equipment storage facility is a certain distance or more away from an average position that is mainly used and when the number of times of replacement requests is also less than or equal to a set value compared to the average value, the type of the diagnostic equipment storage facility is downgraded by one level. The one level refers to, for example, one level of 1→2 and 2→3 in operating system program types of 1~n.

On the other hand, when the position of an extracted diagnostic equipment storage facility deviates by a third set value or less from the average position (S107) and the number of times of replacement requests of the extracted diagnostic equipment storage facility is more than or equal to a fourth set value compared to the average number of times of replacement requests (S108), the type of the diagnostic equipment storage facility is upgraded by one level (S109).

That is, when the position of a specific diagnostic equipment storage facility is a certain distance or closer to an average position that is mainly used and when the number of times of replacement requests is also a set value or more compared to the average value, the type of the operating system program type of the diagnostic equipment storage facility is upgraded by one level.

The adjusted operating system program type is recommended to the PVD chamber of the corresponding PVD chamber type.

This operation increases accuracy by using information that directly gauges, to some extent, the operating system program type of a diagnostic equipment storage facility, that is, the demand. The operating system program type directly represents its use value.

First, the control center 200 finds out diagnostic equipment storage facilities within the same use range and calculates the average type of the operating system program types.

The calculated average type and the type of each of the diagnostic equipment storage facilities within the same use range are compared.

As the result of the comparison, when the difference between the type of a specific diagnostic equipment storage facility and the average type is less than or equal to a fifth set value, the type of the diagnostic equipment storage facility is downgraded by two levels.

For example, when the type of a diagnostic equipment storage facility is small, that is, the original demand is somewhat low and is lower than an average type, that is, the surrounding demand, the type is degraded by two levels.

On the other hand, when the difference between the type of a specific diagnostic equipment storage facility and the average type is equal to or more than a sixth set value, the type of the diagnostic equipment storage facility is upgraded by two levels.

That is, when an operating system program type is large and has an original demand and its demand is higher than the surrounding demand, the type is upgraded by two levels.

The type adjusted in this way is recommended.

This operation accurately adjusts an operating system program type by using information that directly gauges usage within a specific use range.

The operating system program types sequentially classified in accordance with the type values thereof.

For example, small, medium, and large scales are sequentially assigned to types 1, 2, and 3, respectively. The lower the type, the lower the demand. When the demand is low, a lower level of type is used.

First, the control center 200 collects and registers the operating system program types of diagnostic equipment storage facilities within the same use range.

The type of each of the extracted diagnostic equipment storage facilities is extracted.

The average type of the extracted types is calculated.

The calculated average type and the type of each of the extracted diagnostic equipment storage facilities are compared.

As the result of the comparison, when the type of an extracted diagnostic equipment storage facility is a set upper limit type value or more compared to the average type, the type of the diagnostic equipment storage facility is increased by (first set value+first weight).

That is, when an operating system program type has a large difference above the average type, for example, when there is original usage and it is greater than the surrounding usage, the type is adjusted by one or more levels.

On the other hand, when the type of an extracted diagnostic equipment storage facility is a set lower limit type value or less compared to the average type, the type of the diagnostic equipment storage facility is decreased by (first set value+first weight).

That is, when an operating system program type has a large difference below the average type, for example, when there is original usage and it is lower than the surrounding usage, the type is decreased by one or more levels.

This operation can adjust the type at once in consideration of the position of a diagnostic equipment storage facility, an operating system program type, and the number of times of replacement requests.

Each of the set values may be determined on the basis of the average values of the positions of diagnostic equipment storage facilities used in the same category or area, the operating system program types, and the numbers of times of replacement requests. A detailed value is determined in accordance with a demand.

For accurate information, the levels of the operating system program types registered for diagnostic equipment storage facilities can be adjusted proportionally.

The lower the operating system program type, the lower the demand.

When a use type is low, the demand is low, and a small set value results in a more accurate result.

This operation can adjust the type in detail using the difference value between the average position of diagnostic equipment storage facilities within the same use range and the position of a specific diagnostic equipment storage facility.

The difference value represents the degree of use of a corresponding storage facility. When a difference value is moderate, an administrator can adjust the type and can monitor the situation further. This is because additional storage facilities may be created.

Through these difference values, the administrator assesses the situation and determines whether to replace the type.

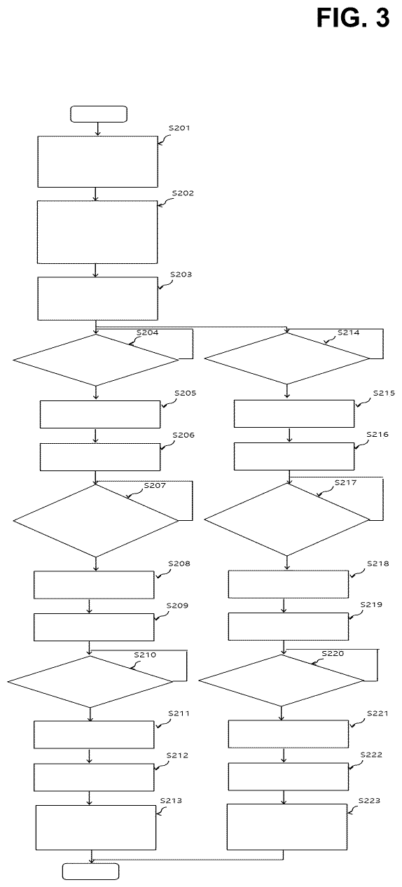

FIG. 3 is a flowchart of the system according to a third embodiment.

Referring to FIG. 3, first, the control center 200 calculates the difference value between the calculated average position of the diagnostic equipment storage facilities within the same use range and the position of each of the diagnostic equipment storage facilities within the range (S201-S205 and S214-S215).

A grade 1 is assigned to the operating system program type of each of the diagnostic equipment storage facilities in proportion to the calculated difference value (S206 and S216).

For example, when the position of a specific diagnostic equipment storage facility is the first set value or more away from the average position of the diagnostic equipment storage facilities within the same use range, a grade 1 (−) is assigned.

On the other hand, when the position is at or less than the fourth set value away from the average position, a grade 1 (+) is assigned.

The grade 1 represents the degree of use depending on the position of a diagnostic equipment storage facility. The higher the grade 1, the higher the degree of use. When the position is close to the average position, it is used more (+), and when it is far from the average position, it is used less (−). This is obtained using the difference between the average position coordinates of the storage facility and the corresponding position coordinates.

The difference value between the calculated average number of times of replacement requests and the number of times of replacement requests of an extracted diagnostic equipment storage facility is calculated (S210-S211 and S220-S221).

A grade 2 is assigned to the type of each diagnostic equipment storage facility in proportion to the calculated difference value (S212 and S222).

For example, when the difference value between the average number of times of replacement requests of diagnostic equipment storage facilities within the same use range and the number of times of replacement requests of a specific diagnostic equipment storage facility is less than or equal to the third set value or less, a grade 2 (−) is assigned.

On the other hand, when the difference value between the average number of times of replacement requests and the number of times of replacement requests of a specific diagnostic equipment storage facility is greater than or equal to a sixth set value, a grade 2 (+) is assigned.

The assigned one level and two levels are summed.

The operating system program type of a corresponding diagnostic equipment storage facility is downgraded by (one level or two levels+grade 1+grade 2) (S213).

Further, the operating system program type of a corresponding diagnostic equipment storage facility is upgraded by (one level or two levels+grade 1+grade 2) (S223).

This increases accuracy by using information that directly gauges the operating system program type of a diagnostic equipment storage facility, that is, the demand.

The control center 200 calculates the difference value between the average type of diagnostic equipment storage facilities within the same use range and the type of each of the extracted diagnostic equipment storage facilities (S201-S205 and S214-S215).

A grade 3 is assigned to the type of each diagnostic equipment storage facility in proportion to the calculated difference value (S207-S209 and S217-S219).

For example, when the difference value between the average type of diagnostic equipment storage facilities within the same use range and the type of a specific diagnostic equipment storage facility is less than or equal to the second set value or less, a grade 3 (−) is assigned.

When the difference value between the average type and the type of the specific diagnostic equipment storage facility is greater than or equal to the fifth set value, a grade 3 (+) is assigned.

The operating system program type of the diagnostic equipment storage facility is downgraded by (one level or two levels+(grade 1+grade 2)×grade 3) (S213).

Further, the operating system program type of the diagnostic equipment storage facility is upgraded by (one level or two levels+(grade 1+grade 2)×grade 3) (S223).

That is, unlike the positions of diagnostic equipment storage facilities and the numbers of times of replacement requests described above, a weight is assigned to an operating system program type that can directly measure a demand, and a grade 3 is applied as a multiplier.

What is claimed is:

1. A system for diagnosing a PVD chamber for manufacturing semiconductors, the system comprising:
multiple pieces of diagnostic equipment for testing a PVD chamber for each factory; and
a control center configured to remotely manage a use state of an operating system program for the diagnostic equipment in conjunction with the diagnostic equipment,
wherein the diagnostic equipment performs:
a first step of testing a corresponding PVD chamber using an operating system program type supplied from the control center;
a second step of setting a type of the PVD chamber in the first step;
a third step of classifying PVD chamber types for types of operating system program types of the diagnostic equipment and setting one of the types for the type of the PVD chamber in the second step, and detecting usage of the operating system program after the second step;
a fourth step of comparing the usage detected in the third step with a set threshold;
a fifth step of detecting a position of the PVD chamber when the detected usage is the threshold or more in the fourth step; and
a sixth step of transmitting the type, position, and operating system program replacement request information of the PVD chamber to the control center in the fifth step, and
wherein the control center performs:
a first step of setting and registering a type and a position of the operating system program of a diagnostic equipment storage facility for a type and a position of each PVD chamber;
a second step of collecting the type, position, and operating system program replacement request information of a PVD chamber for each of the PVD chambers through the diagnostic equipment in the first step;
a third step of extracting the operating system program and the position of a diagnostic equipment storage facility closest to the types and positions of the PVD chambers collected in the second step from the registration information; and
a fourth step of transmitting the information extracted in the third step to corresponding diagnostic equipment.

2. The system of claim 1, wherein the control center further performs:
a fifth step of extracting diagnostic equipment storage facilities within a set use range from the diagnostic equipment storage facilities registered in the first step;
a sixth step of calculating an average position of the diagnostic equipment storage facilities extracted in the fifth step;
a seventh step of comparing the average position calculated in the sixth step and a position of each of the extracted diagnostic equipment storage facilities;
an eighth step of calculating an average number of times of replacement requests of operating system programs of the diagnostic equipment storage facilities extracted in the fifth step;
a ninth step of comparing the average number of times of replacement calculated in the eighth step and the number of times of replacement requests of each of the extracted diagnostic equipment storage facilities;
a tenth step of downgrading the operating system program type of an extracted diagnostic equipment storage facility by one level when the position of the diagnostic equipment storage facility deviates by a first set value or more from the average position and the number of times of replacement requests of the diagnostic equipment storage facility is less than or equal to a second set value compared to the average number of times of replacement requests in the seventh and ninth steps;
an eleventh step of upgrading the operating system program type of an extracted diagnostic equipment storage facility by one level when the position of the diagnostic equipment storage facility deviates by a third set value or less from the average position and the number of times of replacement requests of the diagnostic equipment storage facility is more than or equal to a fourth set value compared to the average number of times of replacement requests in the seventh and ninth steps; and
a twelfth step of recommending the operating program types adjusted in the tenth and eleventh steps to the PVD chamber of a corresponding PVD chamber type.

3. The system of claim 2, wherein the control center further performs:
a thirteenth step of calculating an average type of operating system program types of the diagnostic equipment storage facilities extracted in the fifth step; and
a fourteenth step of comparing the average type calculated in the thirteenth step and the operating system program type of each of the extracted diagnostic equipment storage facilities,
wherein the tenth step downgrades the operating system program type of an extracted diagnostic equipment storage facility when a difference between the operating system program type of the diagnostic equipment storage facility and the average type is less than or equal to a fifth set value in the fourteenth step, and
wherein the eleventh step upgrades the operating system program type of an extracted diagnostic equipment storage facility by two levels when a difference between the operating system program type of the diagnostic equipment storage facility and the average type is more than or equal to a sixth set value in the fourteenth step.

4. The system of claim 3, wherein the control center further performs:
a fifteenth step of collecting and registering operating system program types of diagnostic equipment storage facilities within the same use range in the first step;
a sixteenth step of extracting the operating system program type of each of the extracted diagnostic equipment storage facilities in the fifteenth step;
a seventeenth step of calculating an average type of the operating system program types extracted in the sixteenth step;
an eighteenth step of comparing the average type calculated in the seventeenth step and the operating system program type of each of the extracted diagnostic equipment storage facilities;
a nineteenth step of increasing the operating system program type of an extracted diagnostic equipment storage facility by the one level+first weight when the operating system program type of the diagnostic equipment storage facility is a set upper limit type value or more compared to the average type in the eighteenth step; and
a twentieth step of decreasing the operating system program type of an extracted diagnostic equipment storage facility by the one level+first weight when the operating system program type of the diagnostic equipment storage facility is a set lower limit type value or less compared to the average type in the eighteenth step.
